(19) United States
(12) Patent Application Publication
(10) Pub. No.: US 2009/0243731 A1
(43) Pub. Date: Oct. 1, 2009

(54) Apparatus With Clock Generation Function, Method For Setting Reference Frequency, And Method For Adjusting Reference Frequency

(75) Inventors: Koji TATSUMI, Osaka (JP); Norihisa Uchimoto, Osaka (JP); Kazuhisa Shimazaki, Osaka (JP)

Correspondence Address: HANIFY & KING PROFESSIONAL CORPORATION, 1055 Thomas Jefferson Street, NW, Suite 400, WASHINGTON, DC, 20007, US

(73) Assignee: FUJITSU LIMITED, Kawasaki (JP)

(21) Appl. No.: 12/398,886

(22) Filed: Mar. 5, 2009

(30) Foreign Application Priority Data
Mar. 31, 2008 (JP) 2008-091805

(51) Int. Cl. H03L 7/00

(52) U.S. Cl. 331/18

(57) ABSTRACT

An apparatus includes an oscillator, a memory for storing data of a first frequency and of a first voltage, a first controller for causing the oscillator to generate a clock having a required frequency by applying a voltage on the basis of the data of the first frequency and of the first voltage, a second controller for causing the oscillator to generate a clock having a second frequency by applying a second voltage at predetermined timing, an output section for outputting data of the clock of the second frequency to a frequency counter, a writing section for updating the data of the first voltage to data of the second voltage and the data of the first frequency to data of the second frequency when a difference between the second frequency and a third frequency is within a predetermine range.

### CROSS-REFERENCE TO RELATED APPLICATIONS

This application is based upon and claims the benefit of priority of the prior Japanese Patent Application No. 2008-91805, filed on Mar. 31, 2008, the entire contents of which are incorporated herein by reference.

### FIELD

The embodiments discussed herein are related to an apparatus and a method for reproducing a clock.

### BACKGROUND

Provision of a high-accuracy clock is important when apparatuses such as a CPU and a memory are controlled or when communication is performed between multiple communication apparatuses.

Japanese Laid-open Patent Publication Patent No. 2006-311559 discloses an invention that has an object of providing an accurate reference clock for generating wireless transmissions of a base station in a wireless telephone system.

Japanese Patent No. 3379959 discloses a method for generating a recovered clock signal in response to a phase error signal.

Oscillators, such VCXOs (voltage controlled crystal oscillators), that are used in apparatuses such as commonly distributed personal computers or communication apparatuses and that are used for generating clocks (clock signals) have individual differences. Thus, when the same adjustment value (correction value) is supplied to all apparatuses, some of the apparatuses generate low-accuracy clocks. That is, the apparatuses must be individually adjusted in order to obtain high-accuracy clocks. Even once adjustment is performed, error may increases because of the so-called aging deterioration.

### SUMMARY

According to an aspect of the invention, an apparatus includes an oscillator, a memory for storing data of a first frequency and data of a first value of voltage which is applied to the oscillator in order to generate a clock having the first frequency, a first controller for causing the oscillator to generate a clock having a required frequency by applying a voltage determined on the basis of the data of the first frequency and the data of the first value of voltage, a second controller for causing the oscillator to generate a clock having a second frequency by applying a voltage of a second value at predetermined timing, an output section for outputting data of the clock having the second frequency to a frequency counter, and a writing section for updating the data of the first value of voltage to data of the second value of voltage and the data of the first frequency to data of the second frequency when a difference between the second frequency and a third frequency is within a predetermine range.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a diagram illustrating an example of a connection of A/E converter apparatuses and ATM apparatuses;

FIG. 2 is a diagram illustrating an example of a configuration of the A/E converter apparatus;

FIG. 3 is a diagram illustrating the communication mechanism between two ATM and Ethernet therebetween;

FIG. 4 is a diagram illustrating an example of the configuration for reproducing a clock in the A/E converter apparatus;

FIG. 5 is a flowchart for describing an example of a procedure for test and adjustment; and

FIG. 6 is a flowchart describing an example of processing for correcting error due to aging deterioration.

### DESCRIPTION OF EMBODIMENTS

According to one embodiment of the present invention, an apparatus with a clock generation function includes an oscillator; storing means for storing a first frequency that is a reference frequency and a first level that is a level of a voltage to be applied to the oscillator to cause the oscillator to generate a clock having the first frequency; normal-operation-time oscillator controlling means for causing a clock having a required frequency to be generated by applying a voltage, determined with reference to the first frequency and the first level stored by the storing means, to the oscillator during a normal operation; test-time oscillator controlling means for causing a test clock to be sequentially generated by applying a voltage corresponding to each second level to the oscillator while varying the second level at predetermined timing during test, the second level being a level of a test voltage; test-clock outputting means for outputting the test clock to a frequency counter; and reference-level-and-so-on writing means for causing, when the frequency counter was able to confirm that a difference between a second frequency that is a frequency of the test clock and a third frequency that is a target frequency is in a predetermined range, the storing means to store, as the first level, the second level when the test clock was generated by the oscillator and to store the second frequency of the test clock as the first frequency.

Preferably, the oscillator is a VCXO (voltage controlled crystal oscillator) and the frequency counter is an apparatus for performing number-counting based on a clock generated by a rubidium oscillator.

According to another one embodiment of the present invention, the apparatus with the clock generation function has: data-frame receiving means for receiving data frames that are Ethernet frames containing ATM (asynchronous transfer mode) cells from another apparatus through an Ethernet (registered trademark), the other apparatus being connected to a first ATM apparatus for transmitting data to a second ATM apparatus by using the ATM cells; control-frame receiving means for receiving control frames through the Ethernet, the control frames being Ethernet frames for control and being transmitted by the other apparatus at predetermined time intervals based on a sixth frequency that is a frequency of a clock for communication of the first ATM apparatus; and sixth-frequency determining means for determining the sixth frequency based on time intervals at which the control frames were received, wherein the normal-operation-time oscillator controlling means causes the oscillator to generate, as the clock having the required frequency, a clock having the sixth frequency determined by the sixth-frequency determining means. The apparatus with the clock generation function further has: clock transmitting means for transmitting the clock having the sixth frequency to the second ATM apparatus via an ATM interface, the clock having the sixth frequency being generated by the oscillator caused by the normal-operation-time oscillator controlling means; converting means for converting the received data frames into ATM cells; and ATM cell transmitting means for transmitting the ATM cells, converted by the converting means, to the second ATM apparatus via the ATM interface.

Preferred embodiments of the present invention will be explained with reference to accompanying drawings.

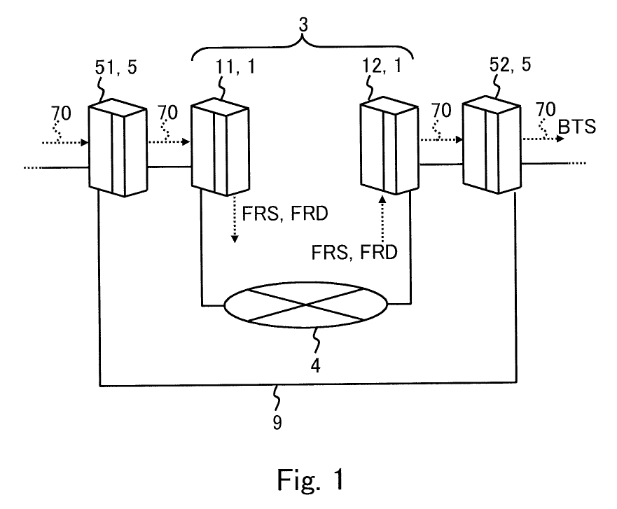

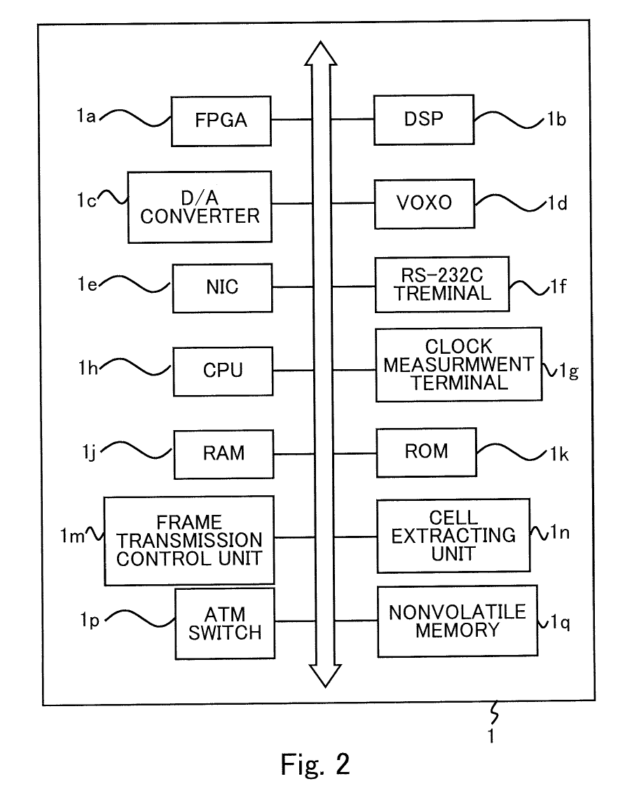

FIG. 1 is a diagram illustrating an example of connection of A/E converter apparatuses 1 and ATM apparatuses 5. FIG. 2 is a diagram illustrating an example of the overall configuration of the A/E converter apparatus 1.

In FIG. 1, the asynchronous transfer mode (ATM) apparatus 5 is an apparatus, such as an ATM terminal or ATM switching equipment having an ATM interface and performs data communication by transmitting/receiving ATM cells to/from another ATM apparatus 5 through an ATM network 9.

An ATM apparatus connection system 3 is constituted by two ATM Ethernet (A/E) converter apparatuses 1. Both of them are interconnected through a wide-area Ethernet 4 and perform data communication by transmitting/receiving Ethernet frames (simply referred to as “frames” hereinafter). One of the A/E converter apparatuses 1 is connected to one of two ATM apparatuses 5, and the other A/E converter apparatus 1 is connected to the other ATM apparatus 5.

The A/E converter apparatus 1 also has a function for converting ATM cells into frames, a function for converting Ethernet frames into ATM cells, a function for causing a clock for data communication of one ATM apparatus 5 to synchronize (slave-synchronize) with a clock for data communication of the other ATM apparatus 5, and so on. With these configurations, the ATM apparatus connection system 3 allows data communication between two ATM apparatuses 5 to be performed thorough the wide-area Ethernet 4 instead of the conventional ATM network 9.

As shown in FIG. 2, the A/E converter apparatus 1 includes an field programmable gate array (FPGA) 1a, a digital signal processor (DSP) 1b, a digital to analog (D/A) converter 1c, a voltage controlled crystal oscillator (VCXO) 1d, an network interface card (NIC) 1e, an RS-232C terminal 1f, a clock measurement terminal 1g, a central processing unit (CPU) 1h, a random access memory (RAM) 1j, a read only memory (ROM) 1k, a frame transmission control unit 1m, a cell extracting unit 1n, an ATM switch 1p, a nonvolatile memory 1q, and so on.

The ATM apparatus 5 may be distinctly referred to as an “ATM apparatus 51”, an “ATM apparatus 52”, hereinbelow. The A/E converter apparatus 1 connected to the ATM apparatus 51 through the ATM interface may be referred to as an “A/E converter apparatus 11”, and similarly, the A/E converter apparatus 1 connected to the ATM apparatus 52 may be referred to as an “A/E converter apparatus 12”.

### [Mechanism of ATM-Ether-ATM Communication]

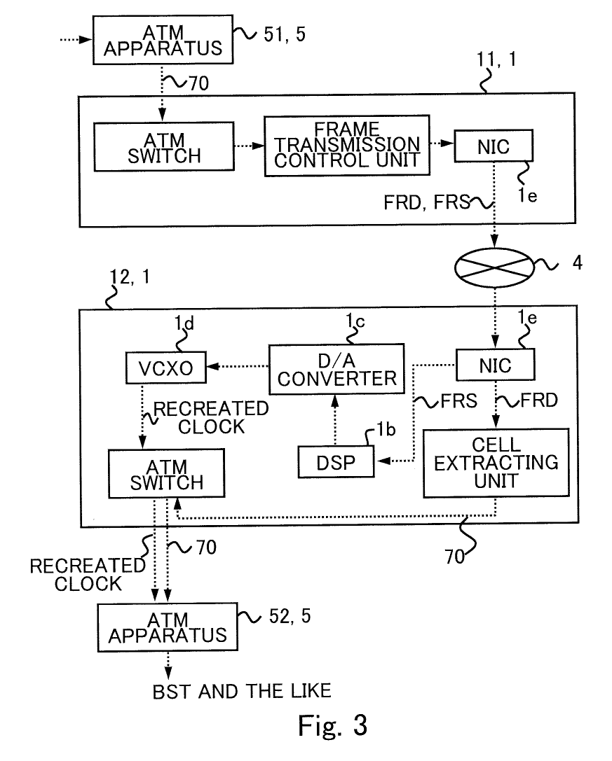

FIG. 3 is a diagram for describing the mechanism of ATM-Ether-ATM communication.

What kind of mechanism is used to cause the ATM apparatus connection system 3, i.e., two A/E converter apparatuses 1, to allow two ATM apparatuses 5 to communicate each other through the wide-area Ethernet 4 instead of the ATM network 9 is described in detail in Japanese Laid-open Patent Publication No. 2006-148822, published on June 8 in Heisei 18, Japanese Laid-open Patent Publication No. 2006-211457, published on Aug. 10, 2006, and Japanese Laid-open Patent Publication No. 2007-166413, published on Jun. 28, 2007. With reference to FIG. 3, how each apparatus functions when data is transmitted from the ATM apparatus 51 to the ATM apparatus 52 by using ATM cells will now be described in conjunction with extracted portions that are particularly highly associated with the present embodiment.

In FIG. 3, the ATM switch 1p in the A/E converter apparatus 11 receives ATM cells 70 from the ATM apparatus 51. The ATM cells 70 are transmitted to the ATM apparatus 52 through the wide-area Ethernet 4 and the A/E converter apparatus 12. That is, the A/E converter apparatus 11 is also an apparatus for relaying the ATM cells 70. Since the A/E converter apparatus 11 is connected to the ATM apparatus 51 via the ATM switch 1p and so on, the A/E converter apparatus 11 obtains information of the frequency of a transmission-side clock, which is a clock for data communication of the ATM apparatus 51, by performing communication with the ATM apparatus 51.

Upon receiving the ATM cells 70, the frame transmission control unit 1m in the A/E converter apparatus 11 converts the ATM cells 70 into data frames FRD which meet an Ethernet protocol. Then, the data frames FRD are transmitted to the A/E converter apparatus 12 through the NIC 1e, the wide-area Ethernet 4, and so on.

In addition, based on the transmission-side clock frequency, the frame transmission control unit 1m transmits control frames FRS, which are frames for control and meet a protocol of the wide-area Ethernet 4, to the A/E converter apparatus 12 through the NIC 1e, the wide-area Ethernet 4, and so on at predetermined time intervals.

In the A/E converter apparatus 12, when the NIC 1e sequentially receives the control frames FRS from the A/E converter apparatus 11, the DSP 1b determines a clock having a frequency that is the same as the transmission-side clock frequency based on the time intervals at which the control frames were received, and controls the D/A converter 1c so that the determined clock is generated (reproduced) from the VCXO 1d. The ATM switch 1p then transmits the reproduced clock to the ATM apparatus 52.

Also, when the NIC 1e in the A/E converter apparatus 12 receives the data frames FRD, the cell extracting unit in extracts the ATM cells 70 from the data frames FRD and sends the ATM cells 70 to the ATM switch 1p. The ATM switch 1p then transmits the ATM cells 70 to the ATM apparatus 52.

### [Achievement of Clock]

Meanwhile, in order to enhance the reliability of transmission of data from the ATM apparatus 51 to the ATM apparatus 52, the accuracy of the clock to be reproduced by the A/E converter apparatus 12 needs to be maintained at a certain level or higher (at high accuracy). Similarly, in order to enhance the reliability of communication in the opposite direction, the accuracy of the clock to be reproduced by the A/E converter apparatus 11 needs to be maintained at a certain level or higher. Accordingly, the A/E converter apparatus 1 is provided with a mechanism for reproducing clocks which is preferably high-accurate. The mechanism will be described below in detail.

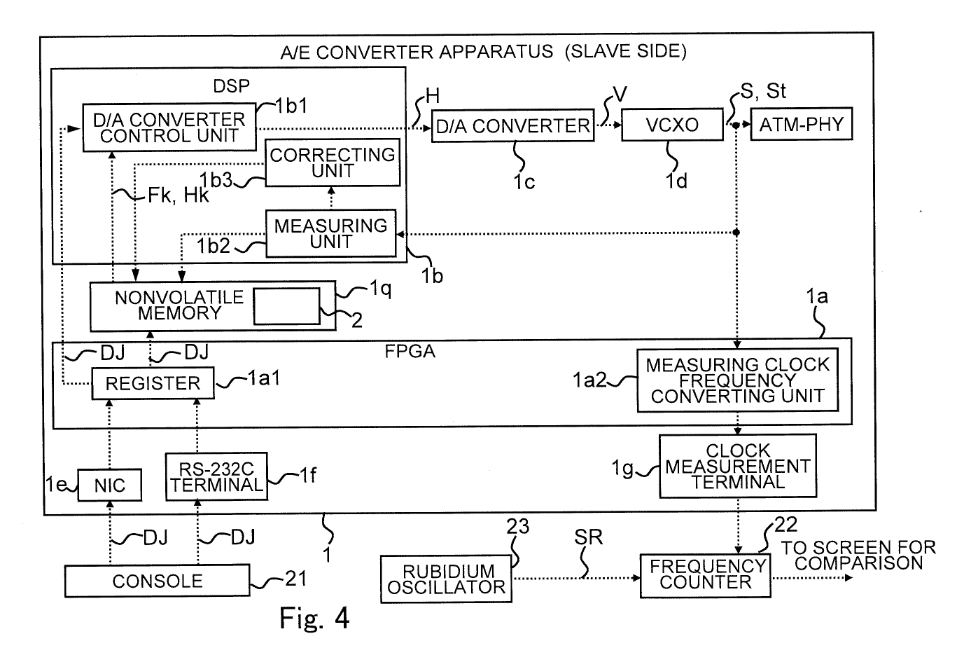

FIG. 4 is a diagram illustrating an example of a configuration for reproducing a high-accuracy clock in the A/E converter apparatus 1.

As shown in FIG. 4, mainly the FPGA 1a, the DSP 1b, the D/A converter 1c, the VCXO 1d, the NIC 1e, the RS-232C terminal 1f, the clock measurement terminal 1g, the nonvolatile memory 1q, and so on are used in order to reproduce a clock which is preferably a high accurate clock. The FPGA 1a includes a register 1a1, a measuring clock-frequency converting unit 1a2, and so on. The DSP 1b includes a D/A-converter controlling unit 1b1, a measuring unit 1b2, a correcting unit 1b3, and so on.

The nonvolatile memory 1q stores a DSP program 2 for processing performed by the D/A-converter controlling unit 1b1 and the measuring unit 1b2, which are described below in sequence. That is, the D/A-converter controlling unit 1b1, the measuring unit 1b2, and the correcting unit 1b3 are achieved by executing the DSP program 2 with a processor. Naturally, the nonvolatile memory 1q may be configured with only a circuit. The nonvolatile memory 1q can also be configured in the DSP 1b.

Although the A/E converter apparatus 1 is also provided with hardware and software for other functions, descriptions thereof are omitted.

A console 21 can be connected to the A/E converter apparatus 1 through the NIC 1e or the RS-232C terminal 1f. In addition, a frequency counter 22 can be connected to the A/E converter apparatus 1 through the clock measurement terminal 1g. A personal computer or the like is used as the console 21. A rubidium oscillator 23 can be connected to the frequency counter 22. A frequency counter 22 including a rubidium oscillator may also be used.

### [Basic Mechanism for Reproducing Clock in A/E Converter Device 1]

The D/A-converter controlling unit 1b1 in the DSP 1b controls the size of analog-voltage information (a voltage value) output from the D/A converter 1c, by outputting a digital control value H to the D/A converter 1c. The digital control value H is a 16-bit serial digital data. The D/A converter 1c converts the digital control value H, which is inputted from the D/A-converter controlling unit 1b1, into an analog voltage value V and outputs the analog voltage value V to the VCXO 1d. A voltage of the voltage value V is applied to the VCXO 1d. As a result, a clock S having a frequency corresponding to the digital control value H is generated from the VCXO 1d and is output to an ATM-PHY.

In this manner, the frequency of the clock S generated by the VCXO 1s is depended on the digital control value H output by the DSP 1b.

The DSP 1b stores reference data indicating that at what frequency the clock S is generated at what value the digital control value H is output. That is, a reference digital control value Hk, which is the digital control value H for generating a clock S having a reference frequency Fk that is a specific frequency, is pre-specified. The nonvolatile memory 1q stores the reference frequency Fk and the reference digital control value Hk. Further, based on the reference frequency Fk and the reference digital control value data Hk (with reference to both of them), the D/A-converter controlling unit 1b1 determines a digital control value H that is optimum for a clock S having a required frequency, and outputs the digital control value H to the D/A converter 1c.

However, when the difference between the value of the original digital control value H for obtaining the reference frequency Fk and the reference digital control value Hk is large, the clock S having a frequency as required cannot be obtained with accuracy.

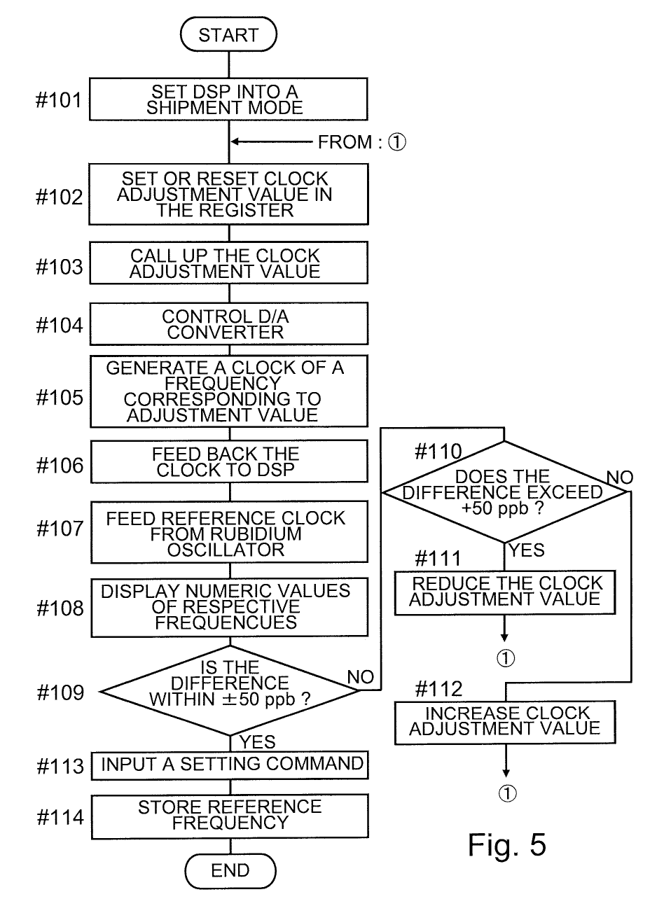

Accordingly, in order to enhance the accuracy of the clock S, test and adjustment are performed according to a procedure as illustrated in FIG. 5, for example, before the shipment of the A/E converter apparatus 1.

### [Test and Adjustment Before Shipment]

FIG. 5 is a flowchart for describing an example of a procedure for test and adjustment.

A person in charge of the test connects the console 21 and the frequency counter 22 to the A/E converter apparatus 1 and turns on power of the A/E converter apparatus 1 in a shipment-mode state. In response, the A/E converter apparatus 1 is started up and the DSP 1b is set into a shipment mode (#101 in FIG. 5). Then, an input of a 16-bit clock adjustment value DJ from the console 21 is waited for.

The person in charge operates the console 21 to input a clock adjustment value DJ to the A/E converter apparatus 1. In this case, the person in charge predetermines a target frequency and inputs a clock adjustment value DJ having a value such that a clock S having a frequency that is as close as possible to the target frequency is generated from the VCXO 1d. For example, when a frequency having the same value as the aforementioned reference frequency Fk is a target frequency, the person in charge may input a clock adjustment value DJ having the same value as or a value close to the aforementioned reference digital control value Hk. The input clock adjustment value DJ is stored in the register 1a1 (#102).

The D/A-converter controlling unit 1b1 calls up the clock adjustment value DJ stored in the register 1a1 (#103), by executing the DSP program 2 stored in the nonvolatile memory 1q. The D/A-converter controlling unit 1b1 then controls the D/A converter 1c (#104) by using the clock adjustment value DJ as the digital control value H. Thus, the VCXO 1d uses the above-described mechanism to generate a clock S having a frequency corresponding to the clock adjustment value DJ (#105). The clock S during test (i.e., the clock corresponding to the clock adjustment value DJ) is referred to as a “clock St”.

The clock St is output to the frequency counter 22 via the measuring clock-frequency converting unit 1a2 and the clock measurement terminal 1g. The clock St is also fed back to the DSP 1b and the frequency is measured by the measuring unit 1b2 (#106).

A clock SR, which is a reference clock, is generated from the rubidium oscillator 23 and is input to the frequency counter 22 (#107). The frequency counter 22 individually counts (counts the numbers of) frequencies of the clock St input from the A/E converter apparatus 1 and frequencies of the clock SR input from the rubidium oscillator 23 and displays numeric values of the respective frequencies (#108). Alternatively, the waveform of the clock St and the waveform of the clock SR may be displayed in a one-above-the-other arrangement or in a superimposed manner.

Meanwhile, in general, error in the frequency of a clock oscillated by a rubidium oscillator is on the order of 0.1 ppb (parts per billion). A 0.05-ppb-class rubidium oscillator is also available.

Thus, the person in charge can determine the difference between the frequency of the clock St and the target frequency in units of 1 ppb, by comparing the displayed information of the clock St and the displayed information of the clock SR. Setting the target frequency to be the same as the frequency of the clock SR or to be N or 1/N the frequency of the clock SR (where N is a natural number) facilitates the comparison.

The person in charge compares both of the information to check whether or not the difference between the frequency of the clock St and the target frequency is in a predetermined range (e.g., in the range of −50 to +50 ppb). When the difference is not in the predetermined range (No in #109), the person in charge re-inputs another value as the clock adjustment value DJ. For example, the person in charge reduces the clock adjustment value DJ (#111) when the difference exceeds +50 ppb (Yes in #110) and increases the clock adjustment value DJ (#112) when the difference is −50 ppb or less (No in #110).

Consequently, the old clock adjustment value DJ is overwritten with the new clock adjustment value DJ and a clock St having a frequency corresponding to the new clock adjustment value DJ is generated from the VCXO 1d. The person in charge compares both of the information again to check whether or not the difference between the frequency of the clock St and the target frequency is in the predetermined range. Thereafter, the person in charge repeats the comparison and check work while varying the value of the clock adjustment value DJ, until the difference is in the predetermined range.

When the difference falls in the predetermined range (Yes in #109), the person in charge operates the consol 21 to input a setting command to the A/E converter apparatus 1 (#113).

In response, the VCXO 1d in the A/E converter apparatus 1 causes the frequency, currently fed back to the DSP 1b and measured by the measuring unit 1b2, to be stored in the nonvolatile memory 1q as the reference frequency Fk, and also causes the clock adjustment value DJ, currently stored in the register 1a1, to be stored in the nonvolatile memory 1q as the digital control value Hk (#114). This completes the test and adjustment processing. After the completion of the processing, the console 21 and the frequency counter 22 are disconnected from the A/E converter apparatus 1.

Thereafter, the A/E converter apparatus 1 that has been shipped and that has started operation determines the value of the digital control value H so that a clock S having a requested frequency is output from the VCXO 1d, with reference to the reference digital control value Hk and the reference frequency Fk stored in the nonvolatile memory 1q, and outputs the determined value to the D/A converter 1c. The above-described clock having the same frequency as the transmission-side clock frequency is also obtained based on the reference digital control value Hk and the reference frequency Fk.

### [Processing for Correcting Error Due to Aging Deterioration]

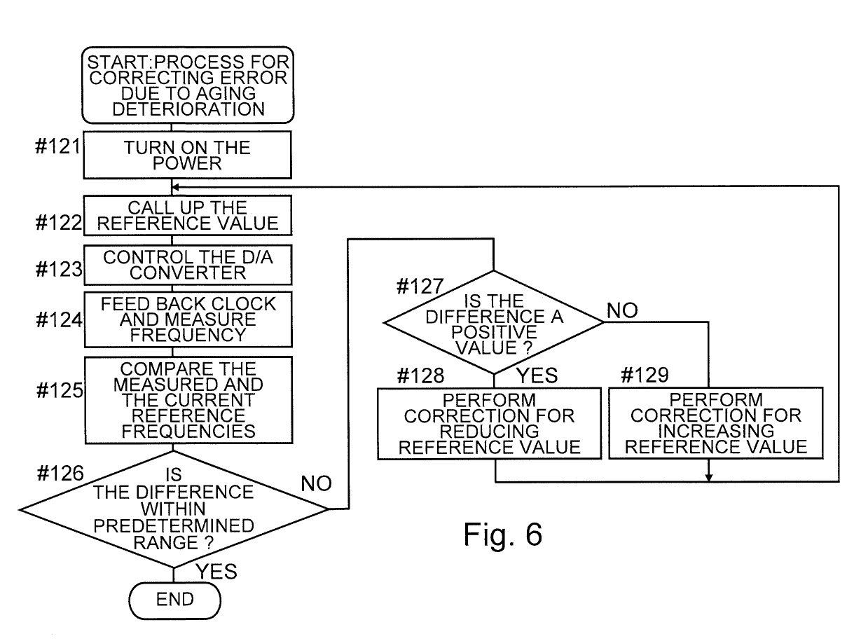

FIG. 6 is a flowchart describing an example of the flow of processing for correcting error due to aging deterioration.

Even when the reference frequency Fk and the reference digital control value Hk in a preferable combination for achieving a high-accuracy clock S can be set by the pre-shipment test and adjustment, the VCXO 1d may not be able to produce a clock S having an accuracy as expected, as years and months pass. That is, the VCXO 1d may produce error due to aging deterioration.

Accordingly, the A/E converter apparatus 1 performs processing for correcting error due to aging deterioration, in accordance with a procedure as shown in FIG. 6.

When the power of the A/E converter apparatus 1 is turned on (#121 in FIG. 6), the D/A-converter controlling unit 1b1 calls up the reference digital control value Hk from the nonvolatile memory 1q (#122), and uses the reference digital control value Hk as the digital control value H to control the D/A converter 1c (#123). In response, a clock S corresponding to the reference digital control value Hk is generated from the VCXO 1d. The clock S is fed back to the DSP 1b and the frequency is measured by the measuring unit 1b2 (#124). Ideally, the frequency should match the reference frequency Fk.

The measurement is continued for a predetermined time (e.g., 30 seconds). Based on the result of the measurement, the correcting unit 1b3 corrects the reference digital control value Hk, as follows.

Throughout the predetermined time, the correcting unit 1b3 determines whether or not the difference between the measured frequency and the current reference frequency Fk is in a control window having a predetermined range (#125).

The predetermined range can be arbitrarily predetermined through the so-called configuration setting. For example, a user can selectively decide one of selections including, for example, “−50 ppb to +50 ppb”, “−100 ppb to +100 ppb”, and “−1 ppb to +1 ppb”. The data of the control window may be pre-stored in the nonvolatile memory 1q. The predetermined time may also be adapted to allow the user to selectively decide one of selections including “30 seconds”, “1 minute”, “10 minutes”, “20 minutes”, and so on.

When the difference is in the control window (Yes in #126), the correcting unit 1b3 determines that aging deterioration that is severe enough to require correction has not occurred, and does not perform correction.

On the other hand, when the difference is not in the control window (No in #126), the correction of the reference digital control value Hk is performed, for example, as follows. When the difference is a positive value (Yes in #127), correction for reducing the reference digital control value Hk is performed (#128). When the difference is a negative value (No in #127), correction for increasing the reference digital control value Hk is performed (#128). Based on the corrected reference digital control value Hk, the processing in steps #123 to #125 is performed again. Then, the correction of the reference digital control value Hk is repeated until the difference is in the control window.

According to the present embodiment, the frequency counter 22 and the rubidium oscillator 23 can be shared by the multiple A/E converter apparatuses 1. Thus, it is possible to set the clock at lower cost and more easily than the conventional ones. After the operation is started, the A/E converter apparatus 1 performs the adjustment (correction) processing by itself, without the frequency counter 22 and the rubidium oscillator 23. Thus, it is possible to maintain the clock more easily than the conventional ones.

In the present embodiment, as described using FIG. 6, the processing for correcting error due to aging deterioration is performed when the power of the A/E converter apparatus 1 is turned on. The processing, however, may be constantly or periodically performed during the operation of the A/E converter apparatus 1.

Although a case in which initial setting and correction of the reference value (the reference digital control value Hk) for the VCXO 1d in the A/E converter apparatus 1 are performed has been described in the present embodiment, the present invention is also applicable to a case in which initial setting and correction of a reference value for an oscillator based on another system are performed.

In addition, the configuration of the entirety or each unit of the A/E converter apparatus 1, the processing contents, the processing procedure, the configuration of the network, and so on can be modified as required, in accordance with the spirit of the present invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An apparatus comprising:
an oscillator;
a memory for storing data of a first frequency and data of a value of a first voltage which is applied to the oscillator in order to generate a clock having the first frequency;
a first controller for causing the oscillator to generate a clock having a required frequency by applying a voltage determined on the basis of the data of the first frequency and the data of the value of first voltage;
a second controller for causing the oscillator to generate a clock having a second frequency by applying a second voltage at predetermined timing;
an output section for outputting data of the clock having the second frequency to a frequency counter; and
a writing section for updating the data of the value of the first voltage to data of the value of the second voltage and the data of the first frequency to data of the second frequency when a difference between the second frequency and a third frequency is within a predetermine range.

2. The apparatus according to claim 1, wherein the oscillator includes a voltage controlled crystal oscillator and the frequency counter counts on the basis of a clock generated by an oscillator including a rubidium oscillator.

3. The apparatus according to claim 1, further comprising:
a third controller for causing the oscillator to generate a clock for examination by applying the voltage having the first value of voltage;
a fourth measure for measuring a fourth frequency of the clock for examination;
a fourth controller for causing the oscillator to generate a clock for adjustment by applying a voltage determined by varying a third value when a difference between the first frequency and the fourth frequency is out of a predetermined range;
a fifth measure for measuring a fifth frequency of the clock for adjustment; and
an updating section for updating data of a fifth value of the voltage as the data of the first value of voltage when a difference between the fifth frequency and the first frequency is within a predetermined range.

4. The apparatus according to claim 1, further comprising an input section for receiving data of the second value, wherein the predetermined timing is a timing when the data of the second value is received by the input section.

5. The apparatus according to claim 1, further comprising:
data frame receiving means for receiving data frames including asynchronous transfer mode cells from another apparatus through an Ethernet, the other apparatus being connected to a first asynchronous transfer mode apparatus for transmitting data to a second asynchronous transfer mode apparatus by using the asynchronous transfer mode cells;
control-frame receiving means for receiving control frames through the Ethernet, the control frames being Ethernet frames for control and being transmitted by the other apparatus at predetermined time intervals based on a sixth frequency that is a frequency of a clock for communication of the first asynchronous transfer mode apparatus;
sixth-frequency determining means for determining the sixth frequency based on time intervals at which the control frames were received, wherein the first oscillator causes the oscillator to generate a clock having the sixth frequency determined by the sixth-frequency determining means;
clock transmitting means for transmitting the clock having the sixth frequency to the second asynchronous transfer mode apparatus via an asynchronous transfer mode interface, the clock having the sixth frequency being generated by the oscillator caused by the first controller;
converting means for converting the received data frames into asynchronous transfer mode cells; and
asynchronous transfer mode cell transmitting means for transmitting the asynchronous transfer mode cells converted by the converting means, to the second ATM apparatus via the asynchronous transfer mode interface.

6. An apparatus with a clock generation function comprising:
an oscillator;
storage means for data of a first frequency and data of a first level of voltage which is applied to the oscillator for generating a clock having the first frequency;
normal operation mode oscillator controlling means for causing a clock having a required frequency to be generated by applying a voltage determined with reference to the first frequency and the first level to the oscillator during a normal operation;
examination operation mode oscillator controlling means for causing a clock for examination by applying a voltage corresponding to the first level of voltage stored in the storage means to the oscillator;
second frequency measuring means for measuring a second frequency of the clock for examination;
adjustment operation mode oscillator controlling means for causing the oscillator to generate a clock for adjustment by applying a voltage corresponding to a second level of voltage for adjustment, the clock for adjustment being generated sequentially by varying the second level of voltage when a difference between the first frequency stored in the storage means and the second frequency measured by the second frequency measuring means is out of a predetermined range;
third frequency measuring means for measuring a third frequency of the clock for adjustment generated by the oscillator; and
reference level updating means for updating the data of the first level to data of the second level and storing the data of the second level when a difference between the third frequency and the first frequency is within a predetermined range.

7. The apparatus with a clock generation function according to claim 6, wherein examination operation mode oscillator controlling means generates the clock for examination.

8. A method for setting a reference frequency and a reference voltage level, the method applicable for an apparatus including an oscillator, a storage for storing data of the reference frequency and data of the reference voltage level of a voltage to be applied to the oscillator for causing the oscillator to generate a clock having the reference frequency, and an oscillator controlling means for causing the oscillator to generate a clock having a required frequency by applying a voltage determined on the basis of the data of the reference frequency and the data of the reference voltage level to the oscillator, the method comprising;
generating a plurality of clocks for examination by applying a voltage to the oscillator, the voltage being corresponding to an examination voltage level which is varied at a predetermine time;
outputting data of the clock for examination to a frequency counter;
storing in the storage data of the examination voltage level instead of the data of the reference voltage level and data of an examination frequency of the clock for examination instead of the reference frequency when a difference between the examination frequency and a desired frequency is within a predetermined range.

9. The method for setting a reference frequency according to claim 8, wherein the oscillator includes a voltage controlled crystal oscillator and the frequency counter counts on the basis of a clock generated by an oscillator including a rubidium oscillator.

10. A method for adjusting a reference frequency and a reference voltage level, the method applicable for an apparatus including an oscillator, a storage for storing data of the reference frequency and data of the reference voltage level of a voltage to be applied to the oscillator for causing the oscillator to generate a clock having the reference frequency, an oscillator controlling means for causing the oscillator to generate a clock having a required frequency by applying a voltage determined on the basis of the data of the reference frequency and the data of the reference voltage level to the oscillator, and a frequency counter for counting a frequency of a clock, the method comprising;
generating a clock for examination by applying a voltage to the oscillator, the voltage being corresponding to the reference voltage level stored in the storage;
measuring an examination frequency of the clock for examination generated by the oscillator;
generating a plurality of clocks for adjustment by applying a voltage to the oscillator, the voltage being corresponding to an adjustment voltage level, the adjustment voltage level being varied when a difference between the reference frequency and the examination frequency measured by the frequency counter is out of a predetermined range;
measuring a frequency of the clock for adjustment by the frequency counter;
storing in the storage data of the adjustment voltage level instead of the data of the reference voltage level when a difference between the frequency of the clock for adjustment and the reference frequency is within a predetermined range.
